(19) United States
(12) Patent Application Publication
(10) Pub. No.: US 2012/0241920 A1
(43) Pub. Date: Sep. 27, 2012

(54) EDGE BEAD REMOVAL FOR POLYBENZOXAZOLE (PBO)

(75) Inventor: Roger Carroll, Rosemount, MN (US)

(73) Assignee: POLAR SEMICONDUCTOR, INC., Bloomington, MN (US)

(21) Appl. No.: 13/425,748

(22) Filed: Mar. 21, 2012

Related U.S. Application Data
(60) Provisional application No. 61/454,857, filed on Mar. 21, 2011.

(51) Int. Cl. H01L 29/02; H01L 21/306

(52) U.S. Cl. 257/632; 438/745; 257/E29.002; 257/E21.219

(57) ABSTRACT

A method of cleaning polybenzoxazole (PBO) from a semiconductor wafer coated with PBO includes baking a PBO-coated semiconductor wafer, and then exposing the semiconductor wafer with ultraviolet light through a patterned mask to soften selected regions of PBO on the semiconductor wafer. PBO is then dissolved in an edge region of the semiconductor wafer with solvent. After dissolving PBO in the edge region, the semiconductor wafer is chemically developed to dissolve the elected softened regions of PBO on the semiconductor wafer and to dissolve PBO remaining in the edge region of the semiconductor wafer that was left behind after the step of dissolving the PBO in the edge region with the solvent.

### CROSS-REFERENCE TO RELATED APPLICATION(S)

This application claims the benefit of U.S. Provisional Application No. 61/454,857 filed Mar. 21, 2011 for “Edge Bead Removal for Polybenzoxazole (PBO)” by Roger Carroll.

### INCORPORATION BY REFERENCE

U.S. Provisional Application No. 61/454,857 is hereby incorporated by reference in its entirety.

### BACKGROUND

The present invention relates to semiconductor wafer processing, and more specifically to a process for effectively cleaning polybenzoxazole (PBO) from the edge of a wafer.

In the process of developing a semiconductor wafer that is patterned with PBO, it is often important to clean the wafer edge via a process known as edge bead removal (EBR). EBR is typically performed by spraying a solvent on the edge region of the wafer, to dissolve PBO on the wafer edge so that the edge region is cleaned. Existing processes of performing EBR can leave residual amounts of PBO in the edge region of the wafer, which can have an undesirable effect on bond pads and/or wire bonds at the edge region of the wafer.

### SUMMARY

The present invention is directed to a method of cleaning polybenzoxazole (PBO) from a semiconductor wafer coated with PBO, and to a semiconductor wafer selectively coated with PBO. A PBO-coated semiconductor wafer is baked, and then exposed with ultraviolet light through a patterned mask to soften selected regions of PBO on the semiconductor wafer. PBO is dissolved in an edge region of the semiconductor wafer with solvent. After dissolving PBO in the edge region, the semiconductor wafer is chemically developed to dissolve the elected softened regions of PBO on the semiconductor wafer and to dissolve PBO remaining in the edge region of the semiconductor wafer that was left behind after the step of dissolving the PBO in the edge region with the solvent.

### BRIEF DESCRIPTION OF THE DRAWINGS

FIG. 1 is a flow diagram illustrating a process of effectively cleaning PBO from the edge of a semiconductor wafer according to an embodiment of the present invention.

FIGS. 2A, 3A, 4A and 5A are perspective views, and FIGS. 2B, 3B, 4B and 5B are section views, of a semiconductor wafer processed according to the process of FIG. 1.

FIG. 6 is a flow diagram illustrating a prior art process of cleaning PBO from the edge of a semiconductor wafer.

FIGS. 7A, 8A, 9A and 10A are perspective views, and FIGS. 7B, 8B, 9B and 10B are section views, of a semiconductor wafer processed according to the process of FIG. 6.

### DETAILED DESCRIPTION

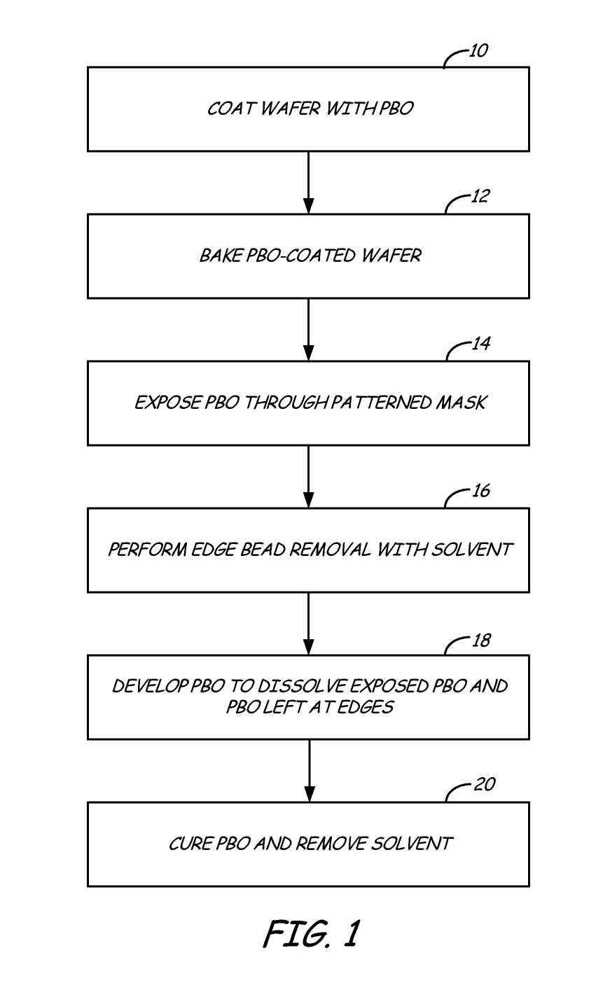

FIG. 1 is a flow diagram illustrating a process of effectively cleaning PBO from the edge of a semiconductor wafer according to an embodiment of the present invention. Initially, in step 10, the wafer is coated with PBO. Next, at step 12, the PBO-coated wafer is baked, which drives off excess solvents and improves the photo-development characteristics of the PBO for future steps. Next, at step 14, the PBO on the wafer is exposed with ultraviolet (UV) light through a patterned mask, softening the exposed regions of PBO. Next, at step 16, EBR is performed by spraying the edge of the semiconductor wafer with solvent, dissolving the PBO in the edge region of the wafer. Next, at step 18, the PBO on the wafer is chemically developed, which dissolves the exposed PBO to form the desired pattern on the wafer, and also dissolves any residual (unexposed) PBO left at the edge region of the wafer after the EBR step. This unexposed PBO at the edge region is dissolved because the chemical development step, in addition to dissolving exposed PBO, also dissolves unexposed PBO at a smaller rate (about 20-30% in most cases) than it dissolves the exposed PBO. Finally, at step 20, the PBO is cured and any remaining solvents are driven off of the wafer. This process results in a clean edge region of the wafer, avoiding the presence of residual PBO that can have a detrimental effect on the bond pads and wire bonds that may be located in the edge region of the wafer.

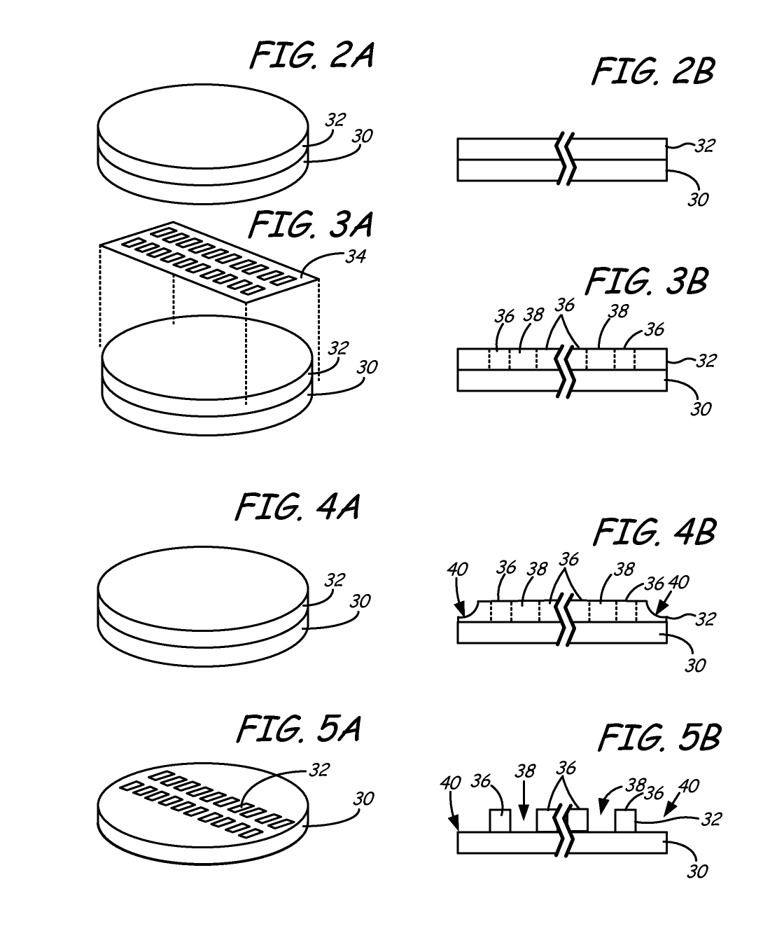

FIGS. 2A, 3A, 4A and 5A are perspective views, and FIGS. 2B, 3B, 4B and 5B are section views, of a semiconductor wafer processed according to the process of FIG. 1. In FIGS. 2A and 2B, wafer 30 is coated with PBO layer 32 and baked (steps 10 and 12, FIG. 1). In FIGS. 3A and 3B, PBO layer 32 on wafer 30 is exposed with UV light through patterned mask 34 to produce unexposed regions 36 and exposed regions 38 (step 14, FIG. 1). In FIGS. 4A and 4B, EBR is performed by spraying solvent on the edge region of wafer 30, dissolving the outer portion of unexposed regions 36 (and leaving residual PBO in outer portions 40 of wafer 30, due to the imperfect EBR process) (step 16, FIG. 1). This leaves a central region of semiconductor wafer 30 with unexposed regions 36 and exposed regions 38. In FIGS. 5A and 5B, wafer 30 is developed, which removes the PBO in exposed regions 38 and also removes residual PBO from outer portions 40 of wafer 30, due to the development process dissolving unexposed PBO at a slower rate than exposed PBO, which is sufficient to dissolve the thin amounts of residual PBO at outer portions 40 of wafer 30 (step 18, FIG. 1).

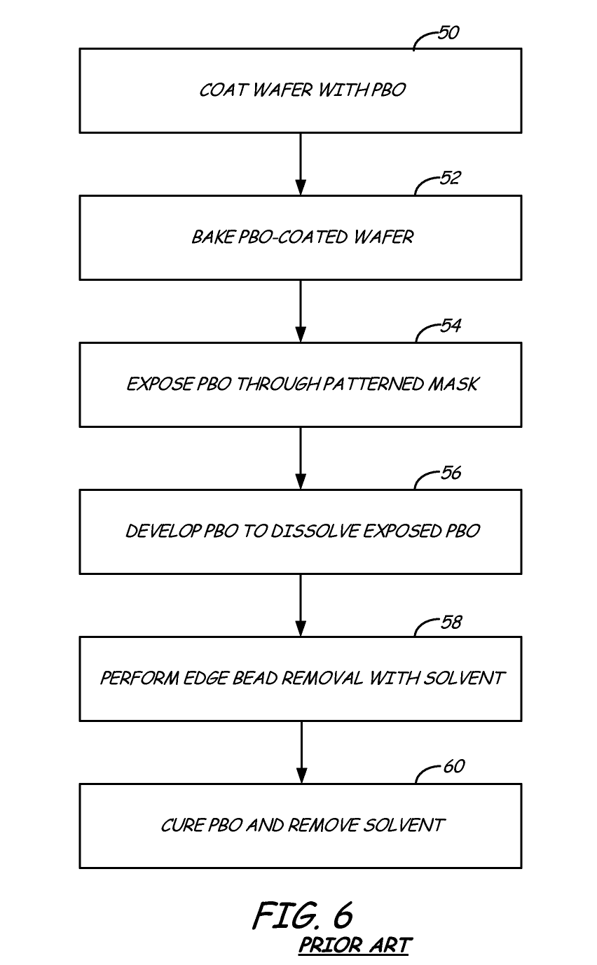

FIG. 6 is a flow diagram illustrating a prior art process of cleaning PBO from the edge of a semiconductor wafer. Initially, in step 50, the wafer is coated with PBO. Next, at step 52, the PBO-coated wafer is baked, which drives off excess solvents and improves the photo-development characteristics of the PBO for future steps. Next, at step 54, the PBO on the wafer is exposed with ultraviolet (UV) light through a patterned mask, softening the exposed regions of PBO. Next, at step 56, the PBO on the wafer is chemically developed, which dissolves the exposed PBO and forms the desired pattern on the wafer. Next, at step 58, EBR is performed by spraying the edge of the semiconductor wafer with solvent, dissolving the PBO in the edge region of the wafer. Finally, at step 60, the PBO is cured and any remaining solvents are driven off of the wafer.

The process shown in FIG. 6 can result in residual amounts of PBO being left on the outer regions of the semiconductor wafer, which can have detrimental effects on the subsequent back grinding process and on the bond pads and/or wire bonds of the wafer. This may occur because the EBR dissolves the PBO at the wafer edge which flows out into the edge region that the EBR is attempting to clean, and/or because droplets of EBR solvent may splash onto the interior of the wafer, locally dissolving PBO that may flow over a bond pad and contaminate it. The process described above with respect to FIG. 1 offers improved performance by developing the PBO after the EBR step has been performed, to ensure that any residual PBO left by the EBR step is dissolved.

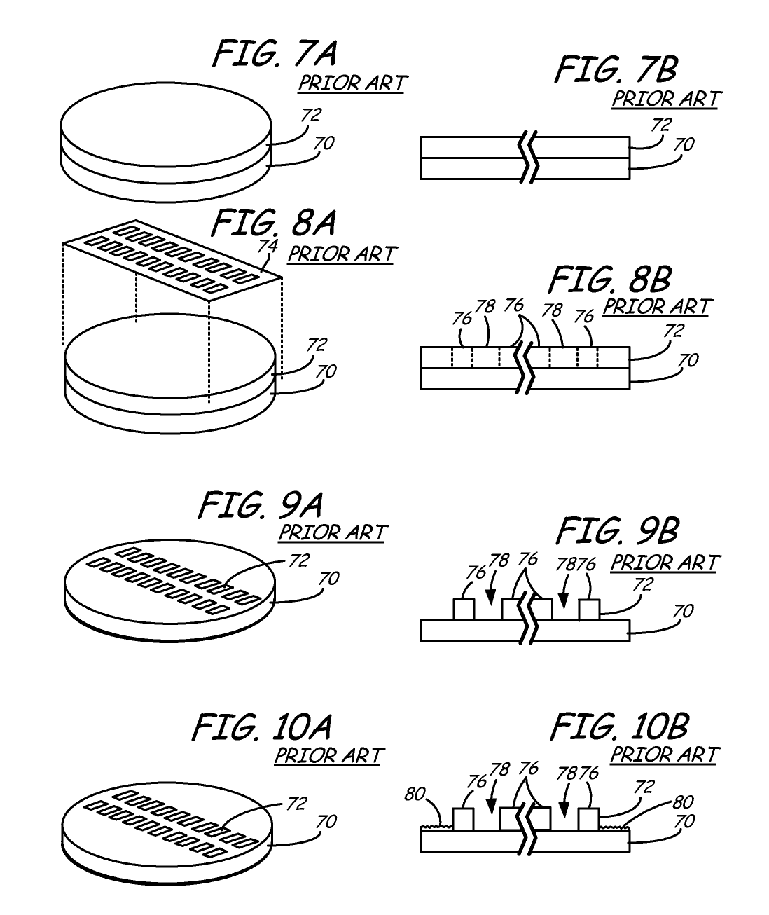

FIGS. 7A, 8A, 9A and 10A are perspective views, and FIGS. 7B, 8B, 9B and 10B are section views, of a semiconductor wafer processed according to the process of FIG. 6. In FIGS. 7A and 7B, wafer 70 is coated with PBO layer 72 and baked (steps 50 and 52, FIG. 6). In FIGS. 8A and 8B, PBO layer 72 on wafer 70 is exposed with UV light through patterned mask 74 to produce unexposed regions 76 and exposed regions 78 (step 54, FIG. 6). In FIGS. 9A and 9B, wafer 70 is developed, which removes the PBO in exposed regions 78 (step 56, FIG. 6). In FIGS. 10A and 10B, EBR is performed by spraying solvent on the edge region of wafer 70. This leaves residual PBO in outer portions 80 of wafer 70, due to the imperfect EBR process (step 58, FIG. 6). As discussed above, the residual PBO in outer portions 80 of wafer 70 can have undesirable effects.

As can be seen from the above description, a more effective process of cleaning the edge region of a semiconductor wafer can be achieved by performing EBR prior to chemically developing the wafer, contrary to the accepted wisdom which suggests that EBR should be performed last (that is, after exposure and development of the wafer).

The above description of the present invention, with reference to FIGS. 1, 2A, 2B, 3A, 3B, 4A, 4B, 5A and 5B, is intended to provide an example of the concept of the invention without necessarily limiting the invention to the scope of the example. For instance, the process described indicates that PBO is exposed by UV light through a patterned mask to soften the exposed regions of PBO on the wafer. In some embodiments, it may be possible to reverse this process so that exposed regions of material are hardened rather than softened, with the pattern of the mask reversed, while proceeding with other steps of the invention essentially as described. Other modifications and permutations of the exemplary steps disclosed herein will be apparent to a person of ordinary skill in the art.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof.

Therefore, it is intended that the invention not be limited to the particular embodiment(s) disclosed, but that the invention will include all embodiments falling within the scope of the appended claims.

1. A method of cleaning polybenzoxazole (PBO) from a semiconductor wafer coated with PBO, the method comprising:
baking the PBO-coated semiconductor wafer;
exposing the PBO on the semiconductor wafer with ultraviolet light through a patterned mask to soften selected regions of PBO on the semiconductor wafer;
dissolving PBO in an edge region of the semiconductor wafer with solvent; and
chemically developing the PBO on the semiconductor wafer, after dissolving PBO in the edge region, to dissolve the selected softened regions of PBO on the semiconductor wafer and PBO remaining in the edge region of the semiconductor wafer.

2. The method of claim 1, wherein the step of chemically developing the PBO on the semiconductor wafer dissolves the unexposed regions of PBO at a smaller rate than it dissolves exposed regions of PBO.

3. The method of claim 2, wherein the step of chemically developing the PBO on the semiconductor wafer dissolves unexposed regions of PBO at a rate that is 20-30% of a rate at which exposed regions of PBO are dissolved.

4. The method of claim 1, wherein the step of dissolving PBO in the edge region of the semiconductor wafer with solvent leaves residual PBO in the edge region.

5. The method of claim 4, wherein the step of chemically developing the PBO on the semiconductor wafer dissolves the residual PBO left in the edge region.

6. A semiconductor wafer selectively coated with polybenzoxazole (PBO), comprising:
an edge region in which all PBO is removed; and
a central region inside the edge region, comprising:
first regions having a cured layer of PBO; and
second regions in which all PBO is removed.

7. The semiconductor wafer of claim 6, wherein the second regions are defined by exposure with ultraviolet light through a patterned mask to soften PBO in the second regions for removal by chemical development of the semiconductor wafer.

8. The semiconductor wafer of claim 7, wherein the edge region is defined by dissolving of PBO with a solvent, and all PBO is removed in the edge region by the chemical development of the semiconductor wafer after dissolving of PBO with the solvent.
